(19) United States
(12) Patent Application Publication
(10) Pub. No.: US 2007/0223571 A1
(43) Pub. Date: Sep. 27, 2007

(54) Decision-feedback equalizer simulator

(76) Inventor: Marlin E. Viss, Santa Rosa, CA (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 11/390,617

(22) Filed: Mar. 27, 2006

(51) Int. Cl. H03H 7/30; H03D 1/04

(52) U.S. Cl. 375/233; 375/346

(57) ABSTRACT

A Decision-Feedback Equalizer Simulator (“DFES”) for predicting a bit-error rate (“BER”) of a transmitted signal through a channel, wherein the transmitted signal includes a repeating pattern having a length of N bits and wherein the transmitted signal is sampled by a bit-error rate tester (“BERT”) that produces a BER value as a function of a decision threshold ν of the BERT (“BERT(ν)”). The DFES may include a decision-feedback equalizer (“DFE”) having a symbol detector, and a processor configured to define a vector of random variables (“X”) in response to determining the BER value, wherein \vec{X} has the same length of N bits as the repeating pattern of the transmitted signal, and determine the BER value in the DFE as a function of a DFE decision threshold z (“BER(z)”) of the symbol detector utilizing \vec{X}.

### BACKGROUND OF THE INVENTION

In modern communication systems, high-speed digital signals are typically passed through transmission channels and/or media that are less than ideal. The transmission channel and/or media transmission characteristics may degrade a transmitted original digital signal to the point that a receiver is unable to accurately differentiate between a received zero and/or one in the received digital signal at the receiver. This problem is more acute for communication test systems that are utilized to test and characterize numerous types of electronic devices (generally known as “devices under test” or “DUTs”) because on the need to accurately characterize the DUTs.

One approach to solve this problem includes compensating the deterministic effects introduced by sources such as frequency dependent losses and non-linear phase of the transmission medium, discontinuities from vias and connectors, etc., to correct the received digital signals using equalization so that the receiver may correctly receive the received digital signals. As an example of this approach, in FIG. 1, a block diagram of an example of an implementation of a known test system 100 is shown. The test system 100 may include a data source 102, transmission channel (i.e., the “channel”) 104, and receiver 106. The receiver 106 may include an equalizer 108 and receiver 110.

As an example of operation, the data source 102 may send a digital input signal 112 through the channel 104 to the receiver 106. It is appreciated by those skilled in the art that the channel 104 is typically less than ideal and therefore usually degrades the digital input signal 112 based on the transmission characteristics of the channel 104. As a result, the channel output signal 114 is the digital input signal 112 degraded by the transmission characteristics of the channel 104. The equalizer 108 then receives the channel output signal 114 and equalizes the channel output signal 114 in an attempt to compensate for the transmission characteristics of the channel 104. The resulting equalized output signal 116 is then passed to the symbol detector 110 that detects the data on the equalized output signal 116.

Examples of the channel 104 in a typical test system 100 are shown in FIGS. 2 and 3. In FIG. 2, a block diagram of an example of an implementation of a known channel 200 in the test system of FIG. 1 is shown. In this example, the channel 200 may include an input cable 202 and an output cable 204. In FIG. 3, a block diagram of another example of an implementation of a known channel 300 in a test system is shown. In this second example, the channel 300 may include the input cable 202 and output cable 206 shown in FIG. 2 and a DUT 302. It is appreciated that by utilizing both implementations that the test system may be calibrated so as to measure the transmission characteristics of the DUT 302.

An example of a known equalizer is shown in FIG. 4. A common type of equalizer is the linear feed-forward equalizer (“LFE”). The LFE is a finite impulse response (“FIR”) linear filter. In FIG. 4, a block diagram of an example of an implementation of a known LFE 400 is shown. The LFE 400 may include a plurality of n time delays r of equal length 402, an accumulator 404, a plurality of n tap coefficients K 406, and a low-pass filter (“LPF”) 408. In an example of operation, the LFE 400 passes an input signal 410 through to both a tap coefficient K₀ 412 of the plurality of n tap coefficients K 406, via signal path 414, and the plurality of time delays 402 via signal path 416. The tap coefficient K₀ 412 is multiplied with the input signal 410 and the result is passed to the accumulator 404. Similarly, as the input signal 410 is passed through the plurality of time delays 402, the input signal 410 is time delayed by each time delay τ(418, 420, 422, and 424, respectively) in the plurality of time delays 402 the resulting time delayed signals 426 are multiplied with a corresponding tap coefficient (K₀ 428, K₁ 430, K₂ 432, K₃ 434, . . . , Kₙ 436, respectively) of the plurality of n tap coefficients K 406. The corresponding results are then sent to the accumulator 404 that accumulates the results. The accumulated result 440 is the passed to the low-pass filter 408 which filters the accumulated result 440 and produces the equalized output 442. As an example, the input signal 410 and the equalized output 442 may correspond to the channel output signal 114 and equalized output signal 116 of FIG. 1.

Generally, it is appreciated by those skilled in the art that there are advantages to utilizing the example LFE 400. A first advantage is that the LFE 400 type of equalizers are generally well-known in the art and are generally easily modeled and/or simulated because of the linear nature of the LFE 400. A second is that the LFE 400 is stable and does not oscillate (i.e., it has a finite impulse response) because there is no feedback path. Additionally, a wide variety of signal impairments may be corrected by the LFE 400 because the delays τ and the number of taps n may be varied independent of the data rate of the transmitted signal. Generally, the type of signal impairments that may be corrected include skin effect, dielectric loss, and multi-path interference.

Unfortunately, the typical design and evaluation of a high-speed digital transmission network with one or more LFEs 400 involves the derivation of the plurality of n tap coefficients K 406. It is appreciated that this usually requires a difficult formal derivation approach with technical expertise utilizing trial and error, inverse filter estimation from S-parameter or TDT channel characterization, or the iterative convergence algorithms of adaptive filters. Generally, there is a need for a closed form method to determine the n tap coefficient K 406 values. A solution to this problem is the use of a Direct Determination Equalization System as described in U.S. patent application Ser. No. 11/090,383, titled “A Direct Determination Equalization System,” filed Mar. 25, 2005, which is herein incorporated by reference in its entirety.

An example of another known equalizer is shown in FIG. 5. Another common type of equalizer is the Decision Feedback Equalizer (“DFE”). Similar to the LFE, the DFE is an infinite impulse response (“IIR”) linear filter. In FIG. 5, a block diagram of an example of an implementation of a known DFE 500 is shown. The DFE 500 may include a front filter 502, a second discrete-time filter 504, a symbol-by-symbol detector 506, and a combiner 508.

In an example of operation, the DFE 500 may receive an analog signal 510 from the channel (not shown), filter it with the front filter 502, and then combine the resulting filter output 512 (which may be either a discrete-time or continuation-time signal) with a feedback signal 514 from the second discrete-time filter 504 to produce a combined signal 516 that is passed to the symbol-by-symbol detector 506. The front filter 502 may be a continuous-time LFE filter. The symbol-by-symbol detector 506 then detects the symbols from the combined signal 516 to produce a received symbols signal 518 that is both output to other devices (not shown) and passed to the second discrete-time filter 504 via signal path 520.

Generally, an advantage of the DFE 500 is that it may be implemented on an integrated circuit (“IC” or “chip”) utilizing less space than a LFE. However, the feedback path generally produces unstable filters and the non-linear nature of the symbol-by-symbol detector 504 generally adds complexity to models or simulations of the DFE 500.

Referring back to FIG. 1, generally, test systems (such as test system 100) incorporating equalization (whether utilizing a LFE or DFE) have difficulties in their respective measurement methodologies because transmitted signals (i.e., digital input signal 112) are often degraded by the channel 104 to a point that traditional test equipment are not able to properly detect the received signals (i.e., channel output signal 114) without first performing equalization of the received signals. Typically, these types of received signals are known as having a “Closed Eye” because of their jitter and amplitude characteristics. Furthermore, while jitter may result in a Closed Eye in time (i.e., horizontal closure), amplitude characteristics in an intersymbol interference (“ISI”) limited system may result in a Closed Eye in voltage (i.e., vertical closure) before a jitter horizontal closure.

Additionally, the receiver 106 is generally not capable of directly measuring the equalized signal (i.e., equalized output signal 116) from the equalizer 108 because in many implementations the equalizer 108 is usually located on the same device (not shown, such as the same IC) as the symbol detector 110. Therefore, there is a need for a system capable of simulating the equalized signal 116 by characterizing the equalized signal 116 after equalization by the equalizer 108.

A number of techniques exist to characterize the test system 100. As an example, one approach involves utilizing a real-time oscilloscope to capture a section of the transmitted signal from the data source 102 through the channel 104 (also known as the received signal, i.e., channel output signal 114, at the receiver 106) and then utilizing post-processing to apply a mathematical model of an equalizer to the captured waveform of the channel output signal 114. Unfortunately, while this approach functions well when the equalizer 108 is implemented utilizing a LFE, it does not function well when the equalizer 108 is implemented utilizing a DFE because, unlike an LFE, the output of a DFE is a string of bits that cannot be measured and manipulated by an oscilloscope. Therefore, a DFE implementation requires a statistical measurement approach. Additionally, current real-time oscilloscopes typically have insufficient bandwidth to measure the response of DFEs. Equivalent-time oscilloscopes have better bandwidth but they still do not work well with DFEs.

Another approach includes utilizing either Time Domain Reflectometry (“TDR”) or a Vector Network Analyzer (“VNA”). These techniques involve first measuring the scattering parameters of the corrupting channel (i.e., channel 104), then utilizing the scattering parameters to simulate the effect of the channel 104 on an ideal waveform (i.e., the digital input signal 112) from the data source 102, and then simulating the corrective effect of the equalizer 108 would have on the corrupted signal (i.e., channel output signal 114). Unfortunately, these approaches have several drawbacks. As an example, the characterization can usually only be done on passive channels. Additionally, only those portions of the channel that can be measured are being simulated and equalized. An actual equalizer, however, is capable of correcting for both the passive channel and also the imperfections of the transmitter. Moreover, full statistical behavior (e.g., the behavior of the test system 100 in the presence of random noise or other uncorrelated interference) is generally unavailable and difficult to predict because both the transmitted signal (i.e., the digital input signal 112) and the channel 104 are being simulated.

Another problem associated with known test system 100 is related to timing aberrations known as “jitter.” In general, an ideal test system 100 transmits the digital input signal 112 as a pure bit stream from the data source 102, through the channel 104, to the receiver 106. The bit stream on the digital input signal 112 has a given timing (i.e., a bit clock) generated by a clock circuit (not shown) at the data source 102. The receiver 106 attempts to regenerate the bit clock at the receiver 106 through the use of a clock and data recovery (“CDR”) circuit (not shown). Unfortunately, timing aberrations (i.e., jitter) of the incoming bit stream on the digital input signal 112 cause problems in the CDR and results in bad sampling of the bit stream data in the digital input signal 112 causing bit errors that increase the Bit Error Rate (“B ER”). Jitter is significant because it is one of the major potential causes for data being received in error. It is appreciated by those skilled in the art that based on an Eye diagram, as the jitter increases the Eye in the Eye diagram closes in the horizontal dimension and the BER figure increases. Eventually, the jitter may increase to the point that receiver 106 will not be able to receive the channel output signal 114 without equalization. A channel output signal 114 of this type is often referred to a signal having a “Closed Eye.”

Therefore, there is a need for system and method to simulate and predict the effect of a DFE in a test system. Additionally, there is a need for a system capable of compensating for the deterministic effects of a channel and data source utilizing a DFE.

### SUMMARY

A Decision-Feedback Equalizer Simulator (“DFES”) for predicting a bit-error rate (“BER”) of a transmitted signal through a channel, wherein the transmitted signal includes a repeating pattern having a length of N bits and wherein the transmitted signal is sampled by a bit-error rate tester (“BERT”) that produces a BER value as a function of a decision threshold ν of the BERT (“BERT(ν)”). The DFES may include a decision-feedback equalizer (“DFE”) having a symbol detector, and a processor configured to define a vector of random variables (“\vec{X}”) in response to determining the BER value, wherein \vec{X} has the same length of N bits as the repeating pattern of the transmitted signal, and determine the BER value in the DFE as a function of a DFE decision threshold z (“BER(z)”) of the symbol detector utilizing \vec{X}.

In an example of operation, the DFES may perform a method that includes receiving a transmitted signal through a channel at a bit-error rate tester (“BERT”), wherein the transmitted signal includes a repeating pattern having a length of N bits, sweeping a decision threshold ν of the BERT across a first range of voltage levels, determining a BER value for each individual bit, in the repeating pattern of the transmitted signal, at each voltage level of the decision threshold ν, defining a vector of random variables (“\vec{X}”) in response to determining the BER value, wherein \vec{X} has the same length of N bits as the repeating pattern of the transmitted signal, and determining the BER value in the DFE as a function of a DFE decision threshold z (“BER(z)”) of the symbol detector utilizing \vec{X}.

Other systems, methods and features of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood with reference to the following figures. The components in the figures are not necessarily to scale, emphasis instead being placed upon illustrating the principles of the invention. In the figures, like reference numerals designate corresponding parts throughout the different views.

FIG. 1 is a block diagram of an example of an implementation of a known test system.

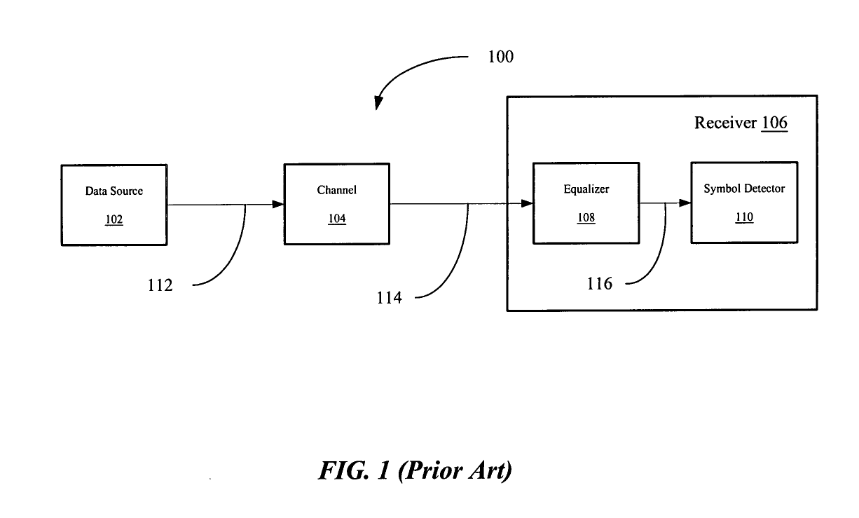

FIG. 2 is a block diagram of an example of an implementation of a known channel in the test system shown in FIG. 1.

FIG. 3 is a block diagram of another example of an implementation of a known channel in a test system shown in FIG. 1.

FIG. 4 is a block diagram of an example of an implementation of a known Linear Feed-forward Equalizer (“LFE”) equalizer shown in FIG. 1.

FIG. 5 is a block diagram of an example of an implementation of a known Decision Feedback Equalizer (“DFE”) equalizer shown in FIG. 1.

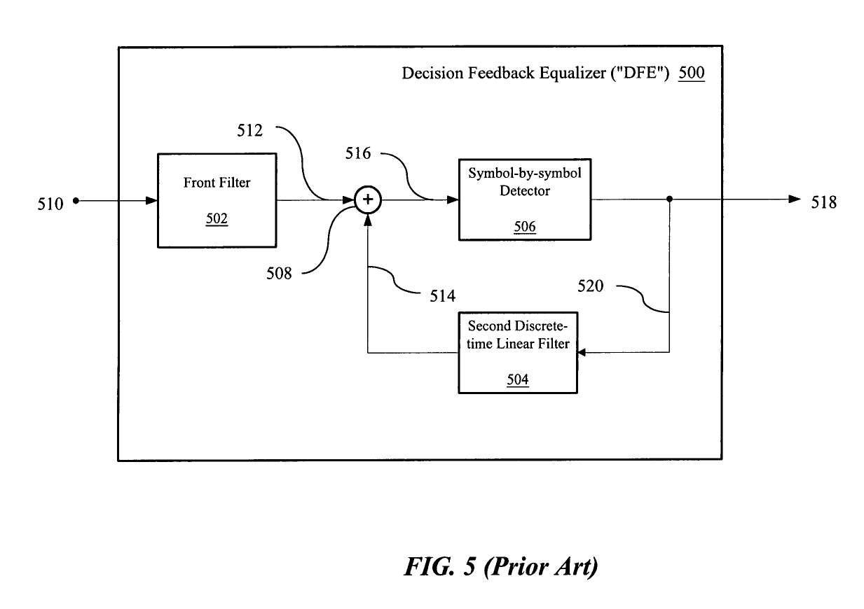

FIG. 6 is a block diagram of an example of an implementation of a new test system utilizing a Decision-Feedback Equalizer Simulator (“DFES”).

FIG. 7 is a block of an example of another implementation of a new test system utilizing a DFES.

FIG. 8 is a block diagram of an example of an implementation of the DFES shown in FIGS. 6 and 7.

FIG. 9 is a plot of an example random variable response.

FIG. 10 is a block diagram of an example of another implementation of the DFES shown in FIGS. 6 and 7.

FIG. 11 is a block diagram of an example of another implementation of the DFES shown in FIG. 7.

FIG. 12 is a flowchart of an example of a process preformed by the DFES shown in FIGS. 6 and 7.

FIG. 13 is a flowchart of an example of a sub-process of the process shown in FIG. 12 preformed by the DFES shown in FIG. 11.

### DETAILED DESCRIPTION

In the following description of the preferred embodiment, reference is made to the accompanying drawings that form a part hereof, and which show, by way of illustration, a specific embodiment in which the invention may be practiced. Other embodiments may be utilized and structural changes may be made without departing from the scope of the present invention.

In general, the invention is a Decision Feedback Equalizer Simulator (“DFES”) that is configured to predict the deterministic effects of a transmission channel (i.e., a channel) and a data source. The DFES is configured to utilize equalizer coefficients to compensate for the deterministic effects of the channel by predicting the Bit-Error Rate (“BER”) given a particular equalizer implementation and a repeating bit stream (also referred to as a “repeating pattern”) measured by an Error Performance Analyzer such as, for example, a bit error rate tester (“BERT”). In general, the DFES predicts the BER of a transmitted signal through a channel, wherein the transmitted signal includes a repeating bit stream having a length of N bits and wherein the transmitted signal is sampled by a BERT that produces a BER value as a function of a decision threshold ν of the BERT (“BER(ν)”). The DFES may include a DFE having a symbol detector, and a processor configured to define a vector of random variables (“\vec{X}”) in response to determining the BER value, wherein \vec{X} has the same length of N bits as the repeating bit stream of the transmitted signal, and determine the BER value in the DFE as a function of a DFE decision threshold z (“BER(z)”) of the symbol detector utilizing \vec{X}.

Example BERT devices may be a N4901B produced by Agilent Technologies, Inc. of Palo Alto, Calif., a BERTScope™ produced by SyntheSys Research, Inc. of Menlo Park, Calif., or a MP1776A produced by Anritsu Company of Morgan Hill, Calif.

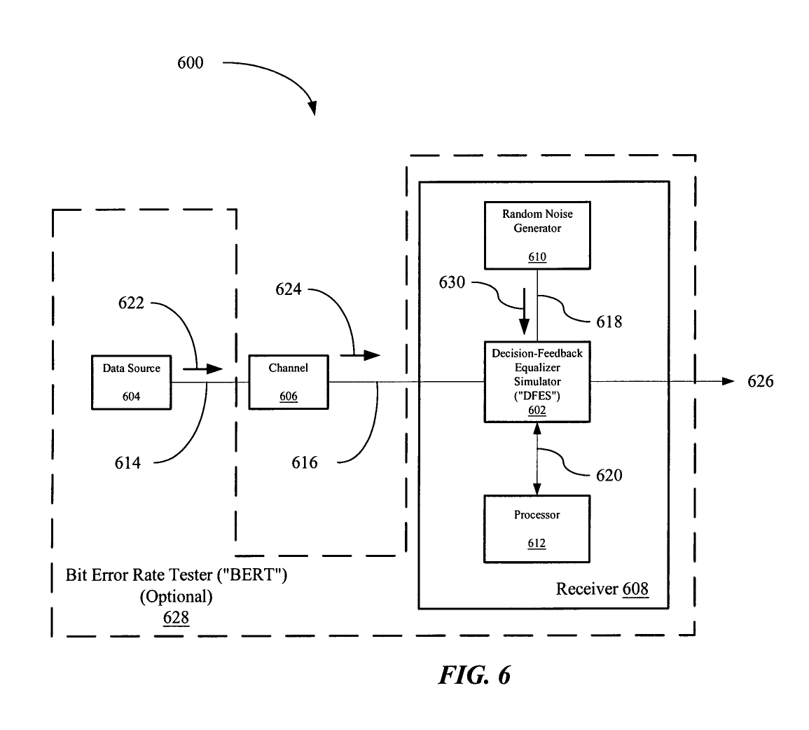

In FIG. 6, a block diagram of an example of an implementation of a new test system 600 utilizing a DFES 602 is shown. The new test system 600 may include a data source 604, transmission channel (i.e., the “channel”) 606, and a receiver 608. The receiver 608 may include the DFES 602, a random noise generator 610, and processor 612. The channel 606 may be in signal communication with both the data source 604 and DFES 602 via signal paths 614 and 616, respectively. Additionally, the DFES 602 may also be in signal communication with both the random noise generator 610 and processor 612 via signal paths 618 and 620, respectively.

As an example of operation, the data source 604 may send a digital input signal 622 through the channel 606 to the receiver 608. It is appreciated by those skilled in the art that the channel 608 is typically less than ideal and therefore usually degrades the digital input signal 622 based on the transmission characteristics of the channel 606. As a result, the channel output signal 624 is the digital input signal 604 degraded by the transmission characteristics of the channel 606. The receiver 608 receives the channel output signal 624 (also known as the “transmitted signal”) and produces a receiver output signal 626 that includes a digital data stream of received symbols.

The data source 604 is any device capable of producing a digital data signal that is receivable by the receiver 608. As an example, the data source 604 and receiver 608 may be modules within an N4910B BERT produced by Agilent Technologies, Inc. of Palo Alto, Calif., a LECROYM1/ADV-1D Oscilloscope produced by LeCroy, Inc. of Chestnut Ridge, N.Y., ME7760B, ME7780A, MP1632C, MP1764, MP1775A, and MP1776A bit error rate test and measurement devices by Anritsu Company of Morgan Hill, Calif., BERTScope™ produced by SyntheSys Research, Inc. of Menlo Park, Calif., or similar devices. The data source 604 and the receiver 608 may both optionally be part of a signal testing system such as, for example, BERT 628.

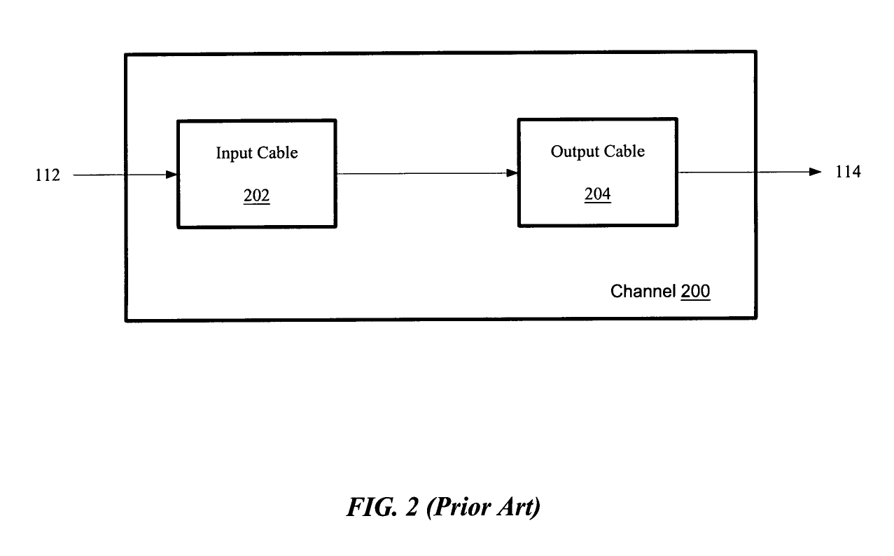

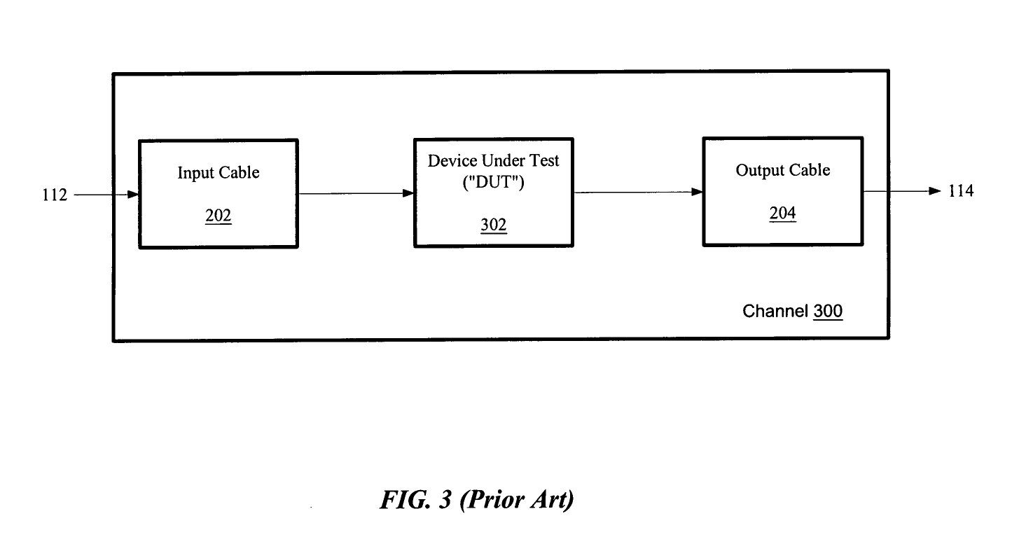

The channel 606 may be similar to the channels 200 and 300 described in FIGS. 2 and 3, respectively. The channel 606 may include an input cable (not shown), output cable (not shown) and a device under test (“DUT”) (not shown).

The processor 612 may be any type of processor, microprocessor, microcontroller, controller, digital signal processor (“DSP”), application specific integrated circuit (“ASIC”), or programmable machine, or similar type of device and/or module. The receiver 608 may also include an optional memory (not shown) that may be any type of storage device, module, or medium capable of storing data from the processor 612. The memory may also store software (not shown) capable of controlling the operation of the processor 612.

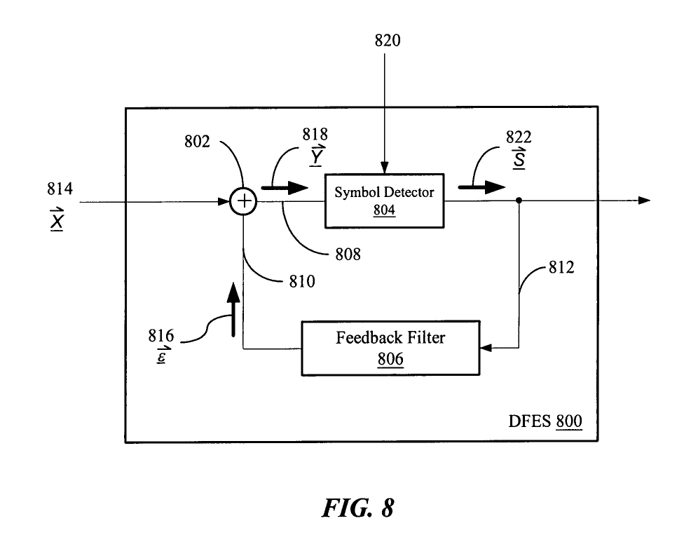

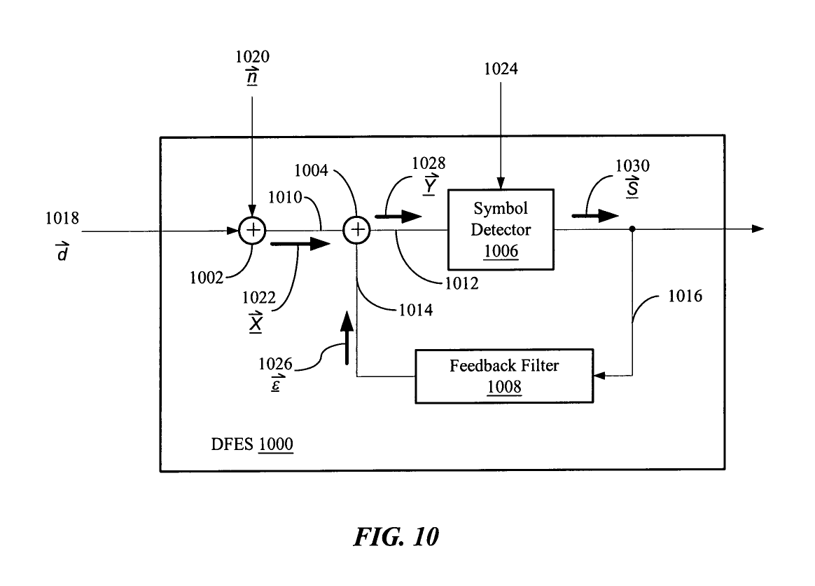

The random noise generator 610 may be any type of device capable of producing a random noise signal 630 having a zero-mean noise process defined by a vector of random variables “n.” The DFES 602 may be implemented as shown in FIGS. 8 and 10.

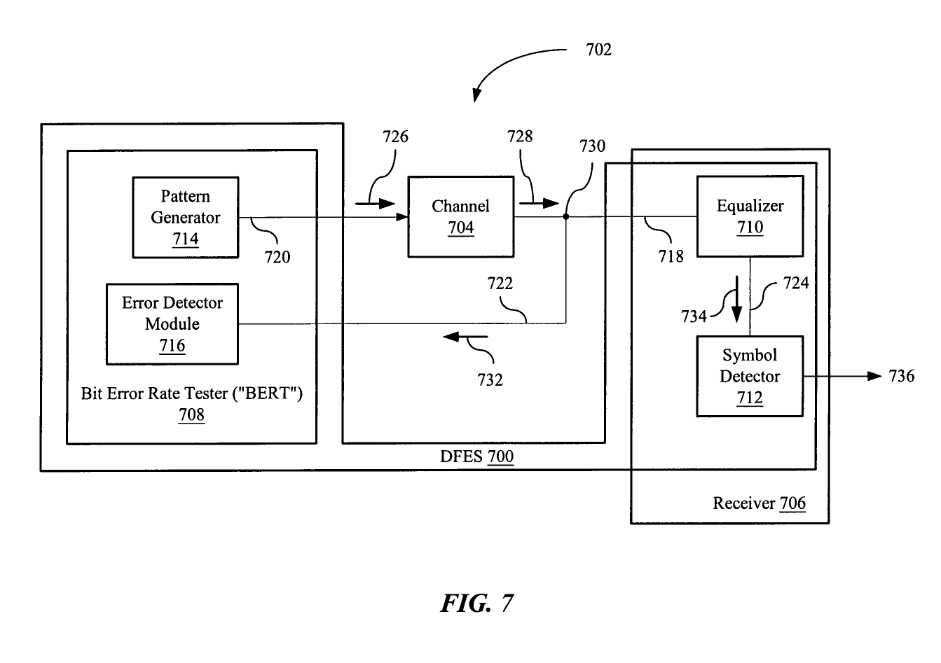

In FIG. 7, a block diagram of an example of an implementation of a DFES 700 with a test system 702 having a transmission channel 704 and a receiver 706 is shown. In this example the DFES 700 may be include individual components or devices, or may be integrated into a signal device. The DFES 700 may include a BERT 708 and an equalizer 710 and symbol detector 712 from the receiver 706. The BERT 708 may include a pattern generator 714 and an error detection module 716. Unlike the example in FIG. 6, where the DFES 600 may be a part of BERT 628, in this example the BERT 708 may be part of the DFES 700.

The channel 704 may be in signal communication with the equalizer 710, pattern generator 714, and error detector module 716 via signal paths 718, 720, and 722, respectively. The Equalizer 710 may also be in signal communication with the symbol detector 712 via signal path 724.

In an example of operation, the pattern generator 714 produces a digital input signal 726 that is sent to the equalizer 710, of the receiver 706, through the channel 704. The channel 706 degrades the digital input signal 726, based on the transmission characteristics of the channel 704, and produces a channel output signal 728. Part of the channel output signal 728 is sampled at a connection point or node 730 between the output of the channel 704 and the input of the receiver 706. The sampled channel output signal 732 is then passed to the error detector module 716 that determines the errors between the channel output signal 728 and the digital input signal 726, which correspond to the errors introduced by the channel characteristics of the channel 704.

The Equalizer 710 may be either a LFE or DFE equalizer and will result in an equalized output signal 734 that is passed to the signal detector 712, which detects the digital symbols from the equalized output signal 734 and produces an output signal 736 of received symbols.

In FIG. 8, a block diagram of an example of an implementation of the DFES 800 of FIG. 6 or 7 is shown. The DFES 800 may include a combiner 802, symbol detector 804, and feedback filter 806. The combiner 802 may be in signal communication with the symbol detector 804 and feedback filter 806 via signal paths 808, and 810, respectively. The symbol detector 804 may also be in signal communication with the feedback filter 806 via signal path 812.

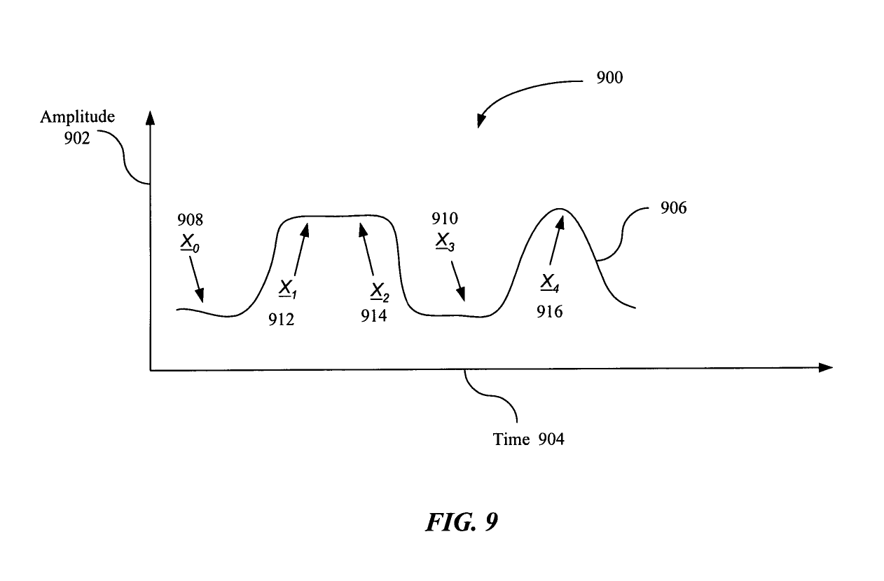

In an example of operation, the DFES 800 may receive a channel output signal 814 (such as, for example, channel output signal 624, FIG. 6, or 728, FIG. 7) from a channel (not shown). As an example, a data source (not shown), such as data source 604 or pattern generator 714, may transmit a data input signal (such as data input signal 622, FIG. 6, or 726, FIG. 7) that includes a repeating sequence of “N” bits. As a result, the channel output signal 814 would also be data signal having a repeating sequence of N bits that may be represented by a vector of random variables defined by \vec{X}=[X₀, X₁, . . . X_{N}] As an example, FIG. 9 shows a plot 900 of amplitude 902 versus time 904 for an example of the vector of random variables \vec{X} 906. In this example, the vector of random variables 906 is shown to have two (i.e., “2”) lower amplitude random variables X₀ 908 and X₃ 910, and three (i.e., “3”) higher value random variables X₁ 912, X₂ 914, and X₄ 916.

Referring back to FIG. 8, the combiner 802 then combines the channel output signal 814 with a feedback signal 816 from the feedback filter 806 into a combined signal 818 and passes the combined signal 818 to the symbol detector 804. The channel output signal 814 may be defined as a vector of random variable \vec{X} that represents an analog signal supplied to the input of the combiner 802 at the instant that the symbol detector 804 makes a decision as determined by a clock signal (not shown). The decision may be based on a decision signal 820 provided by a processor (not shown) such as, for example, the processor 612, FIG. 6, or a processor (not shown) with the BERT 708, FIG. 7.

The combiner 802 then combines the channel output signal 814 with the feedback signal 816 that represents a correction offset (which may be represented by a vector of random variables \vec{ε}) to produce the combined signal 818, which may be represented by a new random vector \vec{Y}, that is passed to the symbol detector 804. The symbol detector 804 then receives the combined signal 818 and produces a detector output signal 822, which may be described by a discrete random variable vector \vec{S}, that may be fed back to the feedback filter 806 via signal path 812.

The symbol detector 804 may include a threshold detector (not shown) that utilizes a decision threshold “z” for determining the bit-error rate (“BER”) seen by the DFES 800. In this example, the BER is a function of z, i.e., BER(z), and is directly proportional to the associated density functions of the combined signal 818 \vec{Y}.

Each random variable has an associated density function fₓ(x) and in the case of a vector of random variables of \vec{X}=[X₀, X₁, . . . X_{N}] the associated vector of density functions is \vec{f}ₓ(x)=[f₀(x₀), (x₁), . . . f_{N}(x_{N})]. Additionally, each random variable also has an associated expected value (i.e., the “mean” value), which may be represented by ηᵢ=E[Xᵢ]. In this case, ideally the expected value ηᵢ equals the transmitted bit (i.e., “ZERO” or “ONE”) in the channel output signal 814 \vec{X} that may be represented as “−1” for a ZERO and “+1” for a ONE. As an example, the vector of random variables \vec{X} 906 in FIG. 9 may be represented by the ideal sequence of expected values \vec{η}′=[−1, +1, +1, −1, +1]. Typically, however, a vector of actual sequence of expected values \vec{η} will be different than the vector of ideal sequence of expected values \vec{η}′ because of inter-symbol-interference (“ISI”) and finite channel bandwidth. An actual expected value vector \vec{η} may be similar to \vec{η}′=E[\vec{X}]=[−0.9, +0.8, +0.9, −0.7, +0.8]. The DFES 800 then chooses equalizer tap values that minimizes the error between the actual expected values \vec{η} and the ideal expected values \vec{η}′, where the minimum error is equal to

$${\sum }_{i} {( {η}_{i}^{′} - {η}_{i} )}^{2} .$$

In the case of the DFES 800 utilizing a DFE (not shown), a rudimentary prediction of BER as a function of the decision threshold (i.e., “z”) of the symbol detector 804 (also known as a symbol “slicer”) may be made by assuming that the DFE operates only on the portion of the combined signal 818 \vec{Y} that is correlated to the transmitted bit sequence (i.e., the channel output signal 814 \vec{X}) and that the DFE has, in the past, made the correct “decision.” Thus in the case of DFE, the DFE may determine the correction offset \vec{ε} for the feedback signal 816 that may be utilized to determine the BER. As a result, \vec{Y}=\vec{X}+\vec{ε} and \vec{ε}=\vec{a}\vec{S}, where \vec{a} is coefficients of the feedback filter 806.

The resulting density of combined signal 818 \vec{Y} is \vec{f}_{y}(y)=\vec{f}ₓ(y−ε)=[f₀(y₀−ε₀), f₁(y₁−ε₁), . . . f_{N}(y_{N}−ε_{N})] with a corresponding cumulative distribution function of

$${F}_{y} ( \underline{y} ) = {\int }_{- ∞}^{\underline{y}} {f}_{y} ( \underline{λ} ) ⅆ \underline{λ} .$$

This may be assembled into a BER prediction by grouping the distributions into those associated with the ZEROs and those associated with the ONEs. The BER(z) seen by the DFES 800 symbol detector 804 as a function of the decision threshold z 820 would be

$$BER ( z ) = \frac{1}{N} ( {\sum }_{i ∈ \{ ZEROs \}} ( 1 - {F}_{{y}_{i}} ( z ) ) + {\sum }_{i ∈ \{ ONEs \}} {F}_{{y}_{i}} ( z ) ) .$$

While this method produces a BER prediction, it is a rudimentary prediction.

The BER prediction may be improved by modifying the above approach as shown in FIG. 10. In FIG. 10, a block diagram of an example of another implementation of the DFES 1000 of FIG. 6 or 7 is shown. The DFES 1000 may include a first combiner 1002, second combiner 1004, symbol detector 1006, and feedback filter 1008. The second combiner 1004 may be in signal communication with the first combiner 1002, symbol detector 1006, and feedback filter 1008 via signal paths 1010, 1012, and 1014, respectively. The symbol detector 1006 may also be in signal communication with the feedback filter 1008 via signal path 1016.

Similar to the DFES 800 of FIG. 8, in an example of operation the DFES 1000 may receive a channel output signal \vec{X} (not shown), such as, for example, channel output signal 624, FIG. 6, or 728, FIG. 7. As an example, a data source (not shown), such as data source 604 or pattern generator 714, may transmit a data input signal (such as data input signal 622, FIG. 6, or 726, FIG. 7) that includes a repeating sequence of “N” bits. As a result, the channel output signal \vec{X} would also be a data signal having a repeating sequence of N bits that may be represented by a vector of random variables defined by \vec{X}=[X₀, X₁, . . . X_{N}].

Unlike the DFES 800 of FIG. 8, in this example the DFES 1000 simulates the channel output signal \vec{X} as a combination of a scalar deterministic vector \vec{d}=[d₀, d₁, . . . d_{N}] combined with a zero-mean noise process defined by a vector of random variables \vec{n}. In this example, the interference introduced by the channel (not shown) may be divided into deterministic signal-dependent interference (such as an ISI and multi-path) and other interference that is not correlated to the bit sequence of the channel output signal (such as crosstalk, random noise, periodic noise, and other similar interference). The deterministic signal-dependent interference may be proportional to the impulse response of the channel.

The scalar deterministic vector \vec{d} represents a dependent interference signal 1018 that is the portion of the channel output signal that is based on deterministic signal-dependent interference from the channel. The random vector \vec{n} represents an uncorrelated interference signal 1020 that is not correlated to the dependent interference signal 1018. The first combiner 1002 then combines the dependent interference signal 1018 with the uncorrelated interference signal 1020 to produce a first combined signal 1022 \vec{X}.

In this example, \vec{X}=\vec{d}+\vec{n} and Xᵢ=dᵢ+nᵢ, where each nᵢ is both independent of each other and independent of dᵢ, and where “i” is the index of the vector ranging from 1 to N. The first combined signal 1022 may represents an analog signal supplied to the input of the second combiner 1004 at the instant that the symbol detector 1006 makes a decision as determined by a clock signal (not shown). The decision may be based on a decision signal 1024 provided by a processor (not shown) such as, for example, the processor 612, FIG. 6, or a processor (not shown) with the BERT 708, FIG. 7.

The second combiner 1004 then combines the first combined signal 1022 with a feedback signal 1026 that represents a correction offset, which may be represented by vector of random variable \vec{ε}, to produce a second combined signal 1028 that may be represented by a new random vector \vec{Y} that is passed to the symbol detector 1006. The symbol detector 1006 then receives the second combined signal 1028 and produces a detector output signal 1030, which may be described by a discrete random variable vector \vec{S}, that may be feed back to the feedback filter 1008 via signal path 1016.

Similar to FIG. 8, the symbol detector 1004 may include a threshold detector (not shown) that utilizes a decision threshold “z” for determining the BER seen by the DFES 800, where the BER(z) is directly proportional to the associated density functions of the combined signal 1028 \vec{Y}. In this example, Yᵢ=Xᵢ+ε=dᵢ+nᵢ+εᵢ and the corresponding density of Yᵢ is then the convolutions of the densities of nᵢ and εᵢ as described by the relationship

$${f}_{{y}_{i}} ( y + {d}_{i} ) = {\int }_{- ∞}^{∞} {f}_{{ɛ}_{i}} ( \underline{λ} ) {f}_{{n}_{i}} ( y - λ ) ⅆ \underline{λ} .$$

This also may be expressed as a convolutions of the distributions of εᵢ and Xᵢ as described by the relationship

$${f}_{{y}_{i}} ( y ) = {\int }_{- ∞}^{∞} {f}_{{ɛ}_{i}} ( \underline{λ} ) {f}_{{X}_{i}} ( y - λ ) ⅆ \underline{λ} .$$

In this example, the random variable \vec{Y} representing combined signal 1028 describes the analog signal immediately before the symbol detector 1006. The discrete random variable vector \vec{S} representing the detector output signal 1030 describes the digital signal immediately after the symbol detector 1006, which may only have binary values of “+1” and “−1” with non-zero probability. As an example, for a fixed decision threshold z, the probability that Sᵢ has on the values “+1” and “−1” are, respectively:
P{Sᵢ=+1}=P{symbol detected as a “ONE”}=1−F_{Y}(z) and
P{Sᵢ=−1}=P{symbol detected as a “ZERO”}=F_{Y}(z),
where F_{Y}(z) is the cumulative distribution function of f_{Y}(z) as defined above.

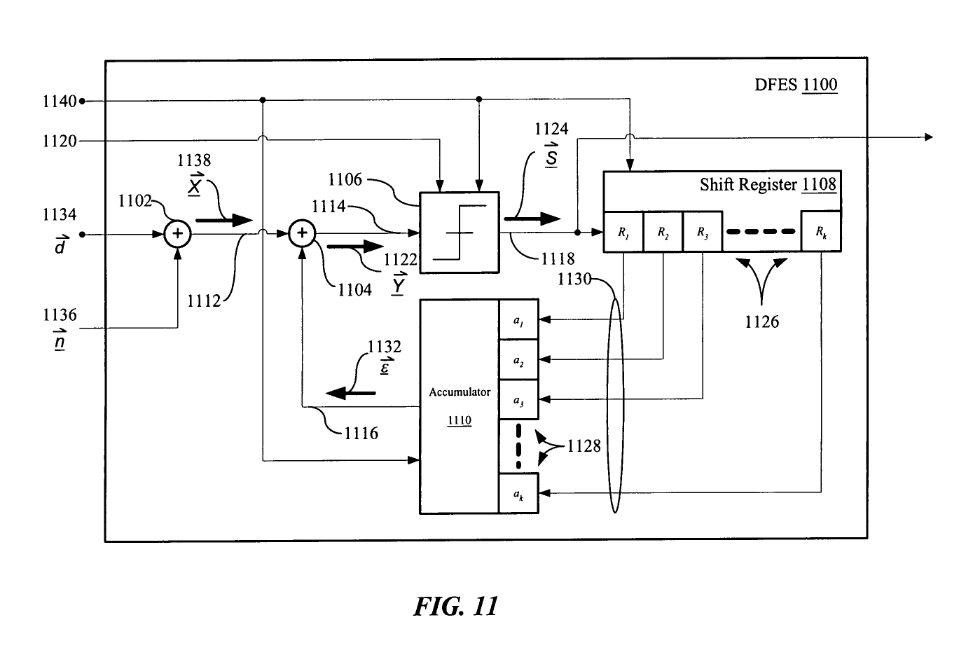

In FIG. 11, a block diagram of an example of an implementation of the DFES 1100 in FIG. 10 is shown. The DFE 1100 may include a first combiner 1102, second combiner 1104, slicer 1106, shift register 1108, and accumulator 1110. The second combiner 1104 may be in signal communication with the first combiner 1102, slicer 1106, and accumulator 1110 via signal paths 1112, 1114, and 1116. The slicer 1006 may be in signal communication with the shift register 1108 via signal path 1118.

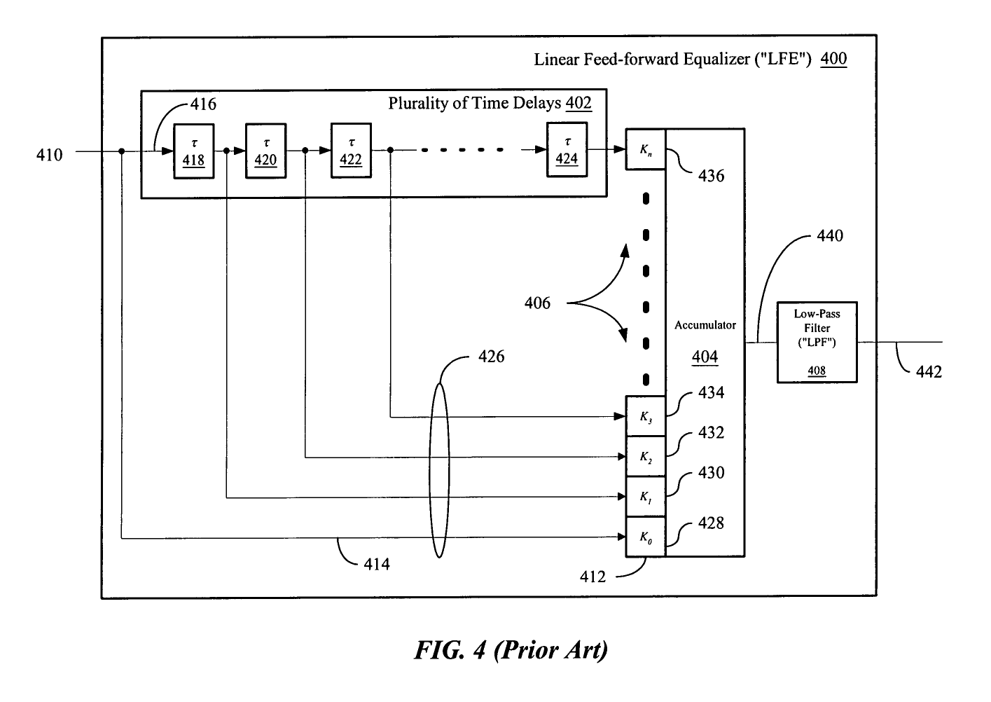

The first combiner 1102 and second combiner 1104 may be summers and the slicer 1106 may be a decision circuit (such as, for example, a symbol detector) that may include a threshold detector (not shown). The slicer 1106 may receive a decision threshold signal 1120 that is utilized by the slicer 1106 to digitize the incoming analog signal 1122 into a slicer output signal 1124 having two distinct digital values. The shift register 1108 is a device capable of delaying the binary slicer output signal 1124 by utilizing a shift register that may include a plurality of “k” binary shifting positions R₁, R₂, R₃, . . . Rₖ 1126. Similar to FIG. 4, the accumulator 1110 is a device having a plurality of k tap coefficients a₁, a₂, a₃, . . . aₖ 1128 that weighs (i.e., multiplies) the plurality of k shifted values 1130 produced by the shift register 1108 and accumulates the results into a correction offset signal 1132 that is fed back to the second combiner 1104 via signal path 1116.

In an example of operation, if a data source (not shown) transmits a data signal that includes a repeating sequence of N bits, the DFES 1100 may receive the channel output signal. Similar to FIG. 10, in this example, the DFES 1100 simulates the channel output signal \vec{X} as a combination of a scalar deterministic vector \vec{d} combined with a zero-mean noise process defined by a vector of random variables \vec{n}.

Again, the scalar deterministic vector \vec{d} represents a dependent interference signal 1134 that is the portion of the channel output signal that is based on deterministic signal-dependent interference from the channel. The random vector \vec{n} represents an uncorrelated interference signal 1136 that is not correlated to the dependent interference signal 1134. The first combiner 1102 then combines the dependent interference signal 1134 with the uncorrelated interference signal 1136 to produce a first combined signal 1138 \vec{X}, which represents an analog signal supplied to the input of the second combiner 1104 at the instant that the slicer 1106 makes a decision as determined by a clock signal 1140 produced by a clock circuit (not shown) in the receiver (not shown). The decision may be based on a decision signal 1120 provided by a processor (not shown) such as, for example, the processor 612, FIG. 6, or a processor (not shown) with the BERT 708, FIG. 7.

The second combiner 1104 then combines the first combined signal 1138 with the correction offset signal 1132, which represents a correction offset that may be represented by the random variable vector \vec{ε}, to produce the second combined signal 1122 (referred to earlier as incoming analog signal 1122) that may be represented by random variable vector \vec{Y} that is passed to the slicer 1106. The slicer 1106 then receives the second combined signal 1122 and produces the slicer output signal 1124 that may be described by the discrete random variable vector \vec{S} that is passed to the shift register 1108. In this example, similar to FIG. 10, each element of \vec{S} may only take on the values of “+1” and “−1” with non-zero probability and are dependent on the decision threshold z of the slicer 1106 that may be determined by the threshold signal 1120 from the processor. Similar to FIG. 10, for a fixed decision threshold z, the probability that S takes on values of “+1” and “−1” are respectively:
P{Sᵢ=+1}=P{symbol detected as a “ONE”}=1−F_{y}(z) and
P{Sᵢ=−1}=P{symbol detected as a “ZERO”}=F_{y}(z).
However, in this example, the correction offset random variable may be produced by the accumulator 1110 by calculating the correction offset as
εᵢ=a₁Siᵢ₋₁+a₂Sᵢ₋₂+ . . . +a_{N}S_{i-N}.

As a result, the DFES 1100 is capable of producing a second combined signal 1122 that is a recursive definition of \vec{Y} as a function of the decision threshold z that may be used with the following relationship

$$BER ( z ) = \frac{1}{N} ( {\sum }_{i ∈ \{ ZEROs \}} ( 1 - {F}_{{y}_{i}} ( z ) ) + {\sum }_{i ∈ \{ ONEs \}} {F}_{{y}_{i}} ( z ) )$$

to predict the BER as a function of the decision threshold z. This is accomplished by representing the analog signal (i.e., the second combined signal \vec{Y} 1122) immediately before the slicer 1106 with the random variable Yᵢ and defining Yᵢ in terms of the input (i.e., Xᵢ 1138) to the DFES 1100 and the feedback signal (i.e., correction offset signal \vec{ε} 1132) of the DFES 1100. The feedback signal is a function of the statistics of the shift register (Sᵢ₋₁, Sᵢ₋₂, . . . Sᵢ₋ₙ), which in turn is a function of the previous random variables (Yᵢ₋₁, Yᵢ₋₂, . . . Yᵢ₋ₙ) and the decision threshold z.

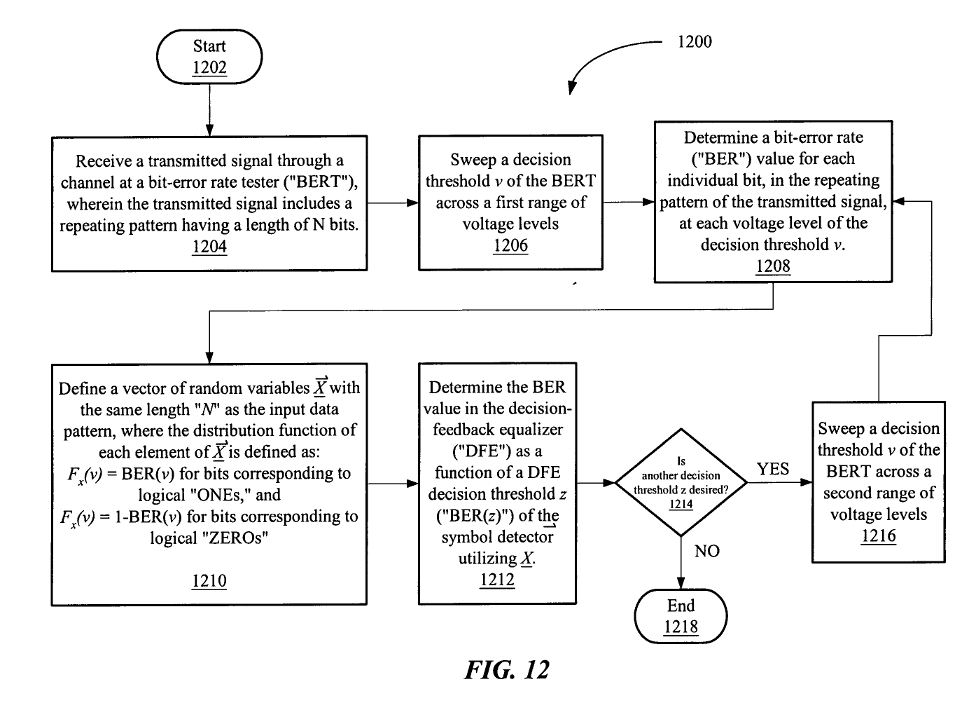

FIG. 12 shows a flowchart 1200 of an example of a process preformed by the DFES in operation. The process begins at step 1202 and in step 1204, the DFES sweeps an input data pattern signal across all the reasonable voltages for a decision threshold ν of a BERT if the BERT is part of the DFES as in FIG. 7. If instead the DFES is part of the BERT (as in FIG. 6), the BERT sweeps an input data pattern signal across all the reasonable voltages for the decision threshold ν of the BERT. This input data pattern signal may be the digital input signal 622 of FIG. 6 or 726 of FIG. 7. As a result, the DFES receives a transmitted signal through a channel at a BERT, wherein the transmitted signal includes a repeating pattern having a length of N bits in step 1204 and, in step 1206, the DFES sweeps the decision threshold ν of the BERT across a first range of voltage levels. The first range of voltage values may be all reasonable voltage values defined by an external user or voltage values predetermined by the BERT or DFES. The process then continues to step 1208, where at each voltage level of decision threshold value ν, the DFES, or BERT, determines a BER for each individual bit in the input data pattern signal (i.e., the repeating pattern or bit-stream), i.e., BER(ν). The DFES, or BERT, then defines a vector of random variables \vec{X} with the same length “N” as the input data pattern, where the distribution function of each element of \vec{X} is defined as Fₓ(ν)=BER(ν) for bits corresponding to logical “ONEs,” and Fₓ(ν)=1−BER(ν) for bits corresponding to logical “ZEROs” in step 1210. The DFES, or BERT, then determines the BER value in the DFE as a function of a DFE decision threshold z (“BER(z)”) of the symbol detector utilizing \vec{X} in step 1212. If another decision threshold z is desired, the process continues through decision step 1214 to step 1216. In step 1216, the DFES sweeps the decision threshold ν of the BERT across a second range of voltage levels and the process repeats steps 1208 through 1212. If no additional decision thresholds are desired, decision step 1214 end the process in step 1218.

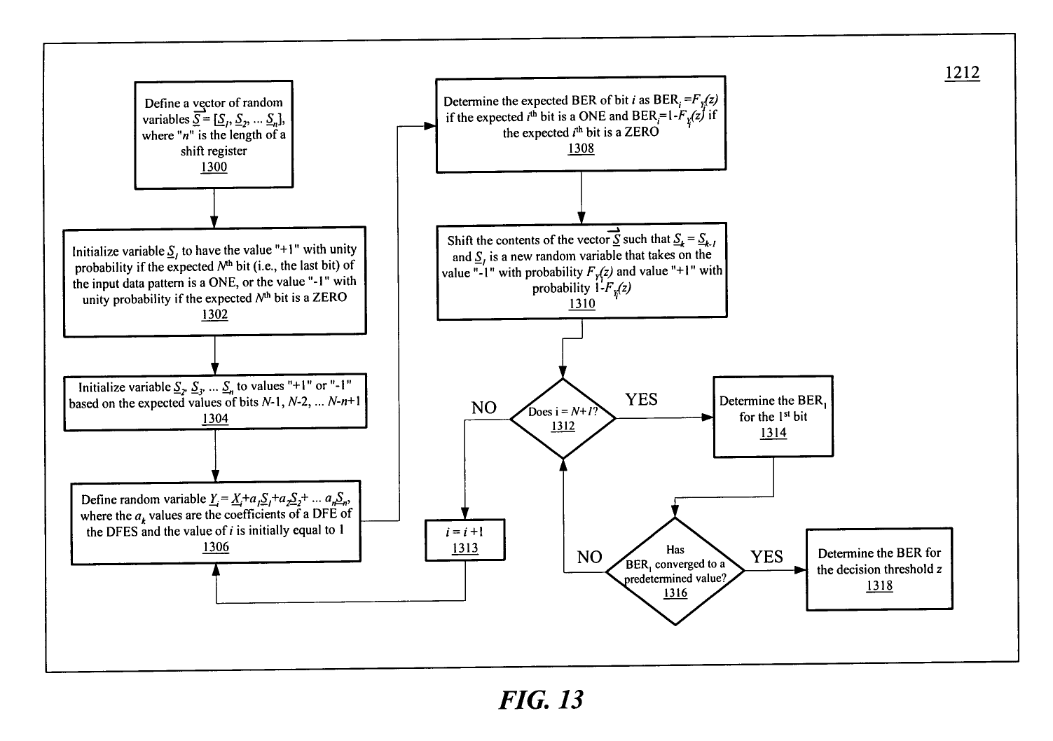

FIG. 13 shows a flowchart of an example of a process preformed by the DFES, or BERT, when determining the BER for a particular decision threshold z of the DFES in step 1212 of FIG. 12. The process begins in step 1300 where the DFES, or BERT, defines a vector of random variables \vec{S}=[S₁, S₂, . . . Sₙ], where n is the length of a shift register 1108 in FIG. 11. The DFES, or BERT, then initializes variable S₁ to have the value “+1” with unity probability if the expected N^{th} bit (i.e., the last bit) of the input data pattern is a ONE, or the value “−1” with unity probability if the expected N^{th} bit is a ZERO in step 1302. The DFES, or BERT, then initializes variables S₂, S₃, . . . Sₙ to values “+1” or “−1” based on the expected values of bits N−1, N−2, . . . N−n+1 in step 1304. In step 1306, the DFES, or BERT, defines random variable Yᵢ=Xᵢ+a₁S₁+a₂S₂+ . . . aₙSₙ, where the aₖ values are the coefficients of a DFE of the DFES and the value of i is initially equal to 1. The DFES then determines, in step 1308, the expected BER of bit i as BERᵢ=F_{Y}_{ᵢ}(z) if the expected i^{th} bit is a ONE and BERᵢ=1−F_{Y}_{ᵢ}(z) if the expected i^{th} bit is a ZERO. In step 1310, the DFES shifts the contents of the vector \vec{S} such that Sₖ=Sₖ₋₁ and S₁ is a new random variable that takes on the value “−1” with probability F_{Y}_{ᵢ}(z) and value “+1” with probability 1−F_{Y}_{ᵢ}(z). The process continues back to step 1306 and the process, between steps 1306 and 1312, is repeated for i=2, 3 . . . until i=N+1. In decision step 1312, if i does not equal N+1, the process returns to step 1306 via step 1313 where i is incremented by 1. Once i equals N+1, decision step 1312 continues the process to step 1314.

In step 1314, the DFES determines BER₁ for the first bit of the input data pattern signal, which will be a different value than the initial value determined for BER₁ because the initial determination assumed the shift register was error free. The process then repeats between steps 1312 and 1316 until the value of BER₁ has converged to within a predetermined value that corresponds to a desired tolerance that may be preprogrammed in the DFES and/or provided by an external user. Once the has converged, decision step 1316 allows the process to continue to step 1318 where the DFES determines the BER for the decision threshold z, i.e., BER(z).

Persons skilled in the art will understand and appreciate, that one or more processes, sub-processes, or process steps described in connection with FIGS. 12 and 13 may be performed by hardware and/or software. Additionally, the DFES may be implemented completely in software that would be executed within a microprocessor, general purpose processor, combination of processors, DSP, and/or ASIC. If the process is performed by software, the software may reside in software memory (not shown) in the DFES 900. The software in software memory may include an ordered listing of executable instructions for implementing logical functions (i.e., “logic” that may be implemented either in digital form such as digital circuitry or source code or in analog form such as analog circuitry or an analog source such an analog electrical, sound or video signal), and may selectively be embodied in any computer-readable (or signal-bearing) medium for use by or in connection with an instruction execution system, apparatus, or device, such as a computer-based system, processor-containing system, or other system that may selectively fetch the instructions from the instruction execution system, apparatus, or device and execute the instructions. In the context of this document, a “computer-readable medium” and/or “signal-bearing medium” is any means that may contain, store, communicate, propagate, or transport the program for use by or in connection with the instruction execution system, apparatus, or device. The computer readable medium may selectively be, for example but not limited to, an electronic, magnetic, optical, electromagnetic, infrared, or semiconductor system, apparatus, device, or propagation medium. More specific examples, but nonetheless a non-exhaustive list, of computer-readable media would include the following: an electrical connection (electronic) having one or more wires; a portable computer diskette (magnetic); a RAM (electronic); a read-only memory “ROM” (electronic); an erasable programmable read-only memory (EPROM or Flash memory) (electronic); an optical fiber (optical); and a portable compact disc read-only memory “CDROM” (optical). Note that the computer-readable medium may even be paper or another suitable medium upon which the program is printed, as the program can be electronically captured, via, for instance, optical scanning of the paper or other medium, then compiled, interpreted or otherwise processed in a suitable manner if necessary, and then stored in a computer memory.

While the foregoing description refers to the use of a DFES, the subject matter is not limited to such a system. Any equalization system that could benefit from the functionality provided by the components described above may be implemented in the DFES.

Moreover, it will be understood that the foregoing description of numerous implementations has been presented for purposes of illustration and description. It is not exhaustive and does not limit the claimed inventions to the precise forms disclosed. Modifications and variations are possible in light of the above description or may be acquired from practicing the invention. The claims and their equivalents define the scope of the invention.

What is claimed:

1. A method for predicting a bit-error rate (“BER”) in a decision-feedback equalizer (“DFE”) utilizing a Decision-Feedback Equalizer Simulator (“DFES”) having a symbol detector, the method comprising:
receiving a transmitted signal through a channel at a bit-error rate tester (“BERT”), wherein the transmitted signal includes a repeating pattern having a length of N bits;
sweeping a decision threshold ν of the BERT across a first range of voltage levels;
determining a BER value for each individual bit, in the repeating pattern of the transmitted signal, at each voltage level of the decision threshold ν;
defining a vector of random variables (“\vec{X}”) in response to determining the BER value, wherein \vec{X} has the same length of N bits as the repeating pattern of the transmitted signal; and
determining the BER value in the DFE as a function of a DFE decision threshold z (“BER(z)”) of the symbol detector utilizing \vec{X}.

2. The method of claim 1, further including transmitting the transmitted signal from a data source within the BERT.

3. The method of claim 1, wherein determining the BER(z) includes determining the BER(z) for a second range of voltage levels.

4. The method of claim 1,
wherein the distribution function of each element of \vec{X} is defined as a distribution function of \vec{X} as a function of the decision threshold ν (“Fₓ(ν)”), wherein Fₓ(ν) is equal to the BER as a function of the decision threshold ν (“BER(ν)”) for bits in \vec{X} that correspond to logical ONEs, and
wherein the distribution function of each element of \vec{X} is defined Fₓ(ν), wherein Fₓ(ν) is equal to one (“1”) minus BER(ν) for bits in \vec{X} that correspond to logical ZEROs.

5. The method of claim 4, wherein determining the BER(z) includes determining the BER(z) for a second range of voltage levels.

6. The method of claim 4, wherein determining the BER(z) includes:
a. defining a vector of random variables \vec{S}, wherein \vec{S}=[S₁, S₂, . . . Sₙ] and wherein “n” is the length in bits of a shift register within the DFE and has a maximum value equal to N;
b. initializing variable S₁;
c. initializing variables S₂ through Sₙ;
d. defining a random variable Yᵢ that is equal to Xᵢ+a₁S₁+a₂S₂+ . . . +aₙSₙ, wherein the aₖ values are coefficients of the DFE and wherein i is that index of each individual bit in the repeating pattern of the transmitted signal and is initially equal to “1”;
e. determining the expected BER value of bit i (“BERᵢ”);
f. shifting the contents of the vector \vec{S} such that \vec{S}=\vec{S}ₖ₋₁;
g. repeating steps (d) through (f) for the rest of the bits in the repeating pattern of the transmitted signal until n equal N;
h. determining a new value for BER₁ for the first bit;
i. repeating steps (g) through (h) until the new value of BER₁ converges to a desired tolerance; and
$$j . determining BER ( z ) as BER ( z ) = \frac{1}{N} {\sum }_{i = 1}^{N} {BER}_{i} .$$

7. The method of claim 6 in step b,
wherein S₁ is initialized to a value equal to “+1” with unity probability if the expected N^{th} bit of the repeating pattern of the transmitted signal is a logical ONE, and
wherein S₁ is initialized to a value equal to “−1” with unity probability if the expected N^{th} bit of the repeating pattern of the transmitted signal is a logical ZERO.

8. The method of claim 7 in step c, wherein variables S₂ through Sₙ are initialized to values “+1” or “−1” based on the corresponding expected values of bits N−1 through N−n+1.

9. The method of claim 7 in step e,
wherein BERᵢ is equal to the distribution function of Yᵢ(z) (“BERᵢ=F_{Y}_{ᵢ}(z)”) if the expected i^{th} bit is value equal to a logical ONE, and
wherein BER₁ is equal to the one “1” minus the distribution function of Yᵢ(z) (“BERᵢ=1−F_{Y}_{ᵢ}(z)”) if the expected i^{th} bit is a logical ZERO.

10. The method of claim 7 in step f,
wherein S₁ is a new random variable that has a value equal to “+1” with probability F_{Y}_{ᵢ}(z), and
wherein S₁ is a new random variable that has a value equal to “−1” with probability 1−F_{Y}_{ᵢ}(z).

11. The method of claim 10, wherein determining the BER(z) includes determining the BER(z) for a second range of voltage levels.

12. A Decision-Feedback Equalizer Simulator (“DFES”) for predicting a bit-error rate (“BER”) of a transmitted signal through a channel, wherein the transmitted signal includes a repeating pattern having a length of N bits and wherein the transmitted signal is sampled by a bit-error rate tester (“BERT”) that produces a BER value as a function of a decision threshold ν of the BERT (“BERT(ν)”), the DFES comprising:
a decision-feedback equalizer (“DFE”) having a symbol detector; and
a processor configured to
define a vector of random variables (“\vec{X}”) in response to determining the BER value, wherein \vec{X} has the same length of N bits as the repeating pattern of the transmitted signal, and
determine the BER value in the DFE as a function of a DFE decision threshold z (“BER(z)”) of the symbol detector utilizing \vec{X}.

13. The DFES of claim 12,
wherein the distribution function of each element of \vec{X} is defined as a distribution function of \vec{X} as a function of the decision threshold ν (“Fₓ(ν)”), wherein Fₓ(ν) is equal to BER(ν) for bits in \vec{X} that correspond to logical ONEs, and
wherein the distribution function of each element of \vec{X} is defined Fₓ(ν), wherein Fₓ(ν) is equal to one (“1”) minus BER(ν) for bits in \vec{X} that correspond to logical ZEROs.

14. The DFES of claim 13, further including the BERT, where the BERT is configured to:
receive the transmitted signal;
sweep the decision threshold ν of the BERT across a first range of voltage levels; and
determine BERT(ν) as a BER value for each individual bit, in the repeating pattern of the transmitted signal, at each voltage level of the decision threshold ν.

15. The DFES of claim 14, wherein the processor is configured to determine the BER(z) for a second range of voltage levels.

16. The DFES of claim 15, further including a data source within the BERT configured to transmit the transmitted signal.

17. The DFES of claim 13, wherein the DFE includes
the symbol detector;
a combiner
wherein the combiner receives the transmitted signal, and
wherein the combiner defines the vector X; and
a feedback filter in signal communication with both the symbol detector and combiner, wherein the feedback filter includes a shift register, and
wherein the feedback filter is configured to define a vector of random variables \vec{S}, wherein \vec{S}=[S₁, S₂, . . . Sₙ] and wherein “n” is the length in bits of the shift register and has a maximum value equal to N,
wherein the processor is configured to
initialize variable S₁,
initialize variables S₂ through Sₙ,
define a random variable Yᵢ that is equal to Xᵢ+a₁S₁+a₂S₂+ . . . +aₙSₙ,
wherein the aₖ values are coefficients of the DFE and wherein i is that index of each individual bit in the repeating pattern of the transmitted signal and is initially equal to “1”,
determine the expected BER value of bit i (“BERᵢ”),
shift the contents of the vector \vec{S} such that Sₖ=Sₖ₋₁,
repeat defining the random variable Yᵢ through shifting the contents of the vector \vec{S} for the rest of the bits in the repeating pattern of the transmitted signal until n equal N;
determining a new value for BER₁ for the first bit,
repeat the repeat defining the random variable Yᵢ through shifting the contents of the vector \vec{S} through determining a new value for BER₁ until the new value of BER₁ converges to a desired tolerance, and
$$determine BER ( z ) as BER ( z ) = \frac{1}{N} {\sum }_{i = 1}^{N} {BER}_{i} .$$

18. The DFES of claim 17,
wherein S₁ is initialized to a value equal to “+1” with unity probability if the expected N^{th} bit of the repeating pattern of the transmitted signal is a logical ONE,
wherein S₁ is initialized to a value equal to “−1” with unity probability if the expected N^{th} bit of the repeating pattern of the transmitted signal is a logical ZERO, and
wherein variables S₂ through Sₙ are initialized to values “+1” or “−1” based on the corresponding expected values of bits N−1 through N−n+1.

19. The DFES of claim 18,
wherein BER₁ is equal to the distribution function of Yᵢ(z) (“BERᵢ=F_{Y}_{ᵢ}(z)”) if the expected i^{th} bit is value equal to a logical ONE, and
wherein BERᵢ is equal to the one “1” minus the distribution function of Yᵢ(z) (“BERᵢ=1−F_{Y}_{ᵢ}(z)”) if the expected i^{th} bit is a logical ZERO,
wherein after shifting, S₁ is a new random variable that has a value equal to “+1” with probability F_{Y}_{ᵢ}(z), and
wherein after shifting, S₁ is a new random variable that has a value equal to “−1” with probability 1—F_{Y}_{ᵢ}(z).

20. The DFES of claim 19, wherein the processor is configured to determine the BER(z) for a second range of voltage levels.
